(19) United States
(12) Patent Application Publication
(10) Pub. No.: US 2013/0168349 A1
(43) Pub. Date: Jul. 4, 2013

(54) METHOD OF FORMING VIA HOLE IN CIRCUIT BOARD

(71) Applicant: Samsung Techwin Co., Ltd., Changwon-city (KR)

(72) Inventors: Soon Chul KWON, Seongnam-si (KR); Sang Min LEE, Seongnam-si (KR)

(73) Assignee: SAMSUNG TECHWIN CO., LTD., Changwon-city (KR)

(21) Appl. No.: 13/727,038

(22) Filed: Dec. 26, 2012

(30) Foreign Application Priority Data
Jan. 3, 2012 (KR) 10-2012-0000603

(51) Int. Cl. H05K 3/22

(52) U.S. Cl. CPC H05K 3/22
USPC 216/17

(57) ABSTRACT

A method of forming a via hole in a circuit board including an insulating layer and a metal layer disposed on each of top and bottom surfaces of the insulating layer, the method including: selectively removing a portion of each of the metal layers where the via hole is to be formed thereby exposing the insulating layer; and removing the exposed insulating layer, wherein the removing of the exposed insulating layer includes chemically swelling the exposed insulating layer and removing the swollen insulating layer.

### CROSS-REFERENCE TO RELATED PATENT APPLICATION

This application claims priority from Korean Patent Application No. 10-2012-0000603, filed on Jan. 3, 2012, in the Korean Intellectual Property Office, the disclosure of which is incorporated herein by reference in its entirety.

### BACKGROUND

1. Field

Methods consistent with exemplary embodiments relate to forming a hole for a conductive pathway in a circuit board, and more particularly, to forming a via hole in a circuit board.

2. Description of the Related Art

As the electronics industry has rapidly developed, various technologies in the fields of electronic device packages and circuit boards have been developed. In particular, as electronic products have become thinner and increasingly miniaturized, demands for forming fine circuit patterns on a substrate, increasing in the number of input/output (I/O) terminals, and providing packages having two or more different functions have increased.

Thus, a circuit board is formed as a multi-layered circuit board, and conductors on layers are electrically connected to one another through vias. A via hole is formed by perforating the circuit board, filling a conductive paste in the via hole, and performing electro/electroless plating.

The related art methods of forming a via hole, such as a mechanical drilling method and a laser drilling method, have been introduced.

### SUMMARY

One or more exemplary embodiments provide a method of forming a via hole in a circuit board, whereby the same quality from the mechanical drilling and the laser drilling of the related art method may be obtained. In using the method of the exemplary embodiments, costs of manufacturing the circuit board may be reduced and the speed of forming the via hole may be increased.

According to an aspect of an exemplary embodiment, there is provided a method of forming a via hole in a circuit board including an insulating layer, and a metal layer disposed on each of top and bottom surfaces of the insulating layer, the method including: selectively removing a portion of each of the metal layers at positions where the via hole is to be formed thereby exposing the insulating layer; and removing the exposed insulating layer. Inner sidewalls of the via hole may be treated by performing a desmear process and/or a plating process if necessary, and predetermined circuit patterns are formed on each of the metal layers after the via hole has been formed.

The removing of the exposed insulating layer may include chemically swelling the exposed insulating layer and removing the swollen insulating layer.

When the insulating layer includes a glass structure material, the removing of the exposed insulating layer may further include etching the glass structure material once or more before or after the removing of the swollen insulating layer.

The selectively removing of the portion of each of the metal layers may include: coating a photosensitive resist on a surface of the each of the metal layers; exposing and developing the photosensitive resist to expose the each of the metal layers based on patterns of the via hole; and etching the each of the exposed metal layers to remove the metal layers and may further include removing the photosensitive resist that remains after the etching of the each of the exposed metal layers.

A solvent selected from the group consisting of an alkaline solution, such as sodium permanganate or sodium hydroxide, an organic solvent, such as acetone, and other acid solutions may be used in the chemically swelling of the exposed insulating layer. By performing the operation of chemically swelling the exposed insulating layer, intermolecular forces of a resin matrix that constitutes a part of the insulating layer, can be so sufficiently reduced that intermolecular combination may be easily separated due to an external shock.

An ultrasonic wave or a high pressure water jet may be used in the removing of the swollen insulating layer.

A range between 28 and 40 kHz of the ultrasonic wave may be used in the removing of the swollen insulating layer.

A pressure of 5 kg/cm² of the high pressure water jet may used in the removing of the swollen insulating layer.

The chemically swelling of the exposed insulating layer may reduce intermolecular forces of the insulating layer within a predetermined range.

According to an aspect of another exemplary embodiment, there is provided a method of forming a via hole in a circuit board comprising, the method including: providing an insulating layer with a first metal layer disposed on a first surface of the insulating layer and a second metal layer disposed on a second surface opposite of the first surface of the insulating layer; exposing a portion of each of the first and second surfaces of the insulating layer by removing a metal layer portion of each of the metal layers; reducing intermolecular forces of the insulating layer by applying a chemical solvent to the exposed portion of the insulating layer; applying a physical external force to remove the exposed portion of the insulating layer thereby forming the via hole; and performing a desmear process on inner sidewalls of the via hole.

The insulating layer may include a glass structure material, and the method may also include etching the glass structure material.

The exposing the portion of each of the first and second metal layers may include: coating a photosensitive resist on a surface of the each of the first and second metal layers; exposing and developing the photosensitive resist to expose the each of the first and second metal layers based on patterns of the via hole; and etching the each of the exposed first and second metal layers to remove the portions of each of first and second metal layers.

### BRIEF DESCRIPTION OF THE DRAWINGS

The above and/or other aspects of the disclosure will become more apparent by describing in detail exemplary embodiments, taken in conjunction with the accompanying drawings of which:

FIGS. 1A through 1D are schematic cross-sectional views of a circuit board for illustrating an operation of exposing an insulating layer by selectively removing metal layers in which a via hole is formed in a method of forming a via hole in the circuit board, according to an exemplary embodiment;

FIGS. 2A and 2B are schematic cross-sectional views of the circuit board illustrated in FIGS. 1A through 1D illustrating an operation of forming a via hole by removing the exposed insulating layer;

FIGS. 3A and 3B are photos showing a via hole formed in the circuit board illustrated in FIG. 2; and

FIGS. 4A through 4C are schematic cross-sectional views of the circuit board for illustrating an operation of manufacturing the circuit board after the via hole has been formed, as illustrated in FIGS. 2A and 2B.

### DETAILED DESCRIPTION

Hereinafter, exemplary embodiments will now be described in detail with reference to the accompanying drawings. In the drawings, corresponding processes and elements may be schematically simplified or partially omitted within the scope of the inventive concept where understanding of the inventive concept is not disturbed, and the same or similar elements are represented by the same or similar reference numerals.

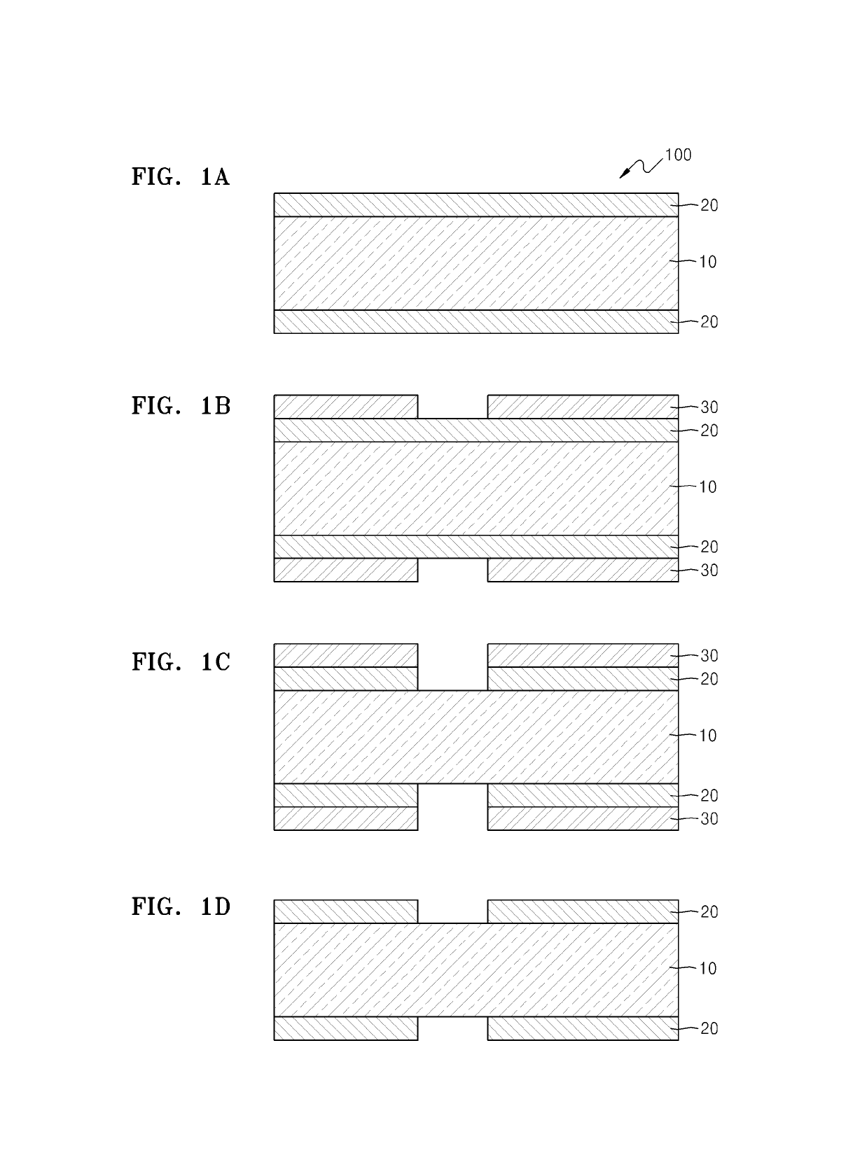

FIGS. 1A through 1D are schematic cross-sectional views of a circuit board 100 for illustrating an operation of exposing an insulating layer 10 by selectively removing metal layers 20 in which a via hole is to be formed in a method of forming a via hole in the circuit board 100, according to an exemplary embodiment.

Referring to FIG. 1A, the circuit board 100 includes an insulating layer 10 and two metal layers 20 respectively placed on top and bottom surfaces of the insulating layer 10. The circuit board 100 may be similar to a copper clad laminate (CCL). The circuit board 100 may be a circuit board for a semiconductor chip package or a printed circuit board (PCB). Predetermined circuit patterns are provided on each of the metal layers 20. The insulating layer 10 supports the circuit board 100 and blocks electrical connection between the metal layers 20. Thus, via holes for electrical connection between the metal layers 20 are formed at predetermined positions through the insulating layer 10.

FIGS. 1A through 1D illustrate an operation, known as a window forming operation, of exposing the insulating layer 10 by selectively removing the metal layers 20 in which a via hole is to be formed in a method of forming a via hole in the circuit board 100 according to an exemplary embodiment. The positions where the metal layers 20 are to be removed and the position where a corresponding insulating layer 10 is to be exposed by the metal layers 20 are predetermined when circuit patterns for the circuit board 100 are designed.

The operation of removing the metal layers 20 based on patterns of the predetermined circuit may be performed by selectively exposing the metal layers 20 corresponding to the patterns of the via hole by using a lithography process and by etching the metal layers 20.

In the operation of removing the metal layers 20, a photosensitive resist 30 is coated on a surface of each of the metal layers 20, and the photosensitive resist 30 is exposed and developed using a via hole pattern mask (not shown) to form preparatory patterns of the photosensitive resist 30 for selectively exposing portions of the metal layers 20 corresponding to the positions in which a via hole is to be formed (see FIG. 1B). Subsequently, the exposed portions of the metal layers 20 are removed by etching using an etchant in a state where unexposed portions of the metal layers 20 are masked by the preparatory patterns of the photosensitive resist 30. Thus, the insulating layer 10 is exposed at the position corresponding to the patterns of the via hole (see FIG. 1C).

The preparatory patterns of the photosensitive resist 30 that remains after the metal layers 20 have been etched may be removed before or after a through hole is formed in the insulating layer 10. However, since the quality of forming the via hole may be lowered due to reacting with a chemical agent used in swelling the exposed insulating layer 10, the preparatory patterns of the photosensitive resist 30 may be immediately removed after the metal layers 20 are etched (see FIG. 1D).

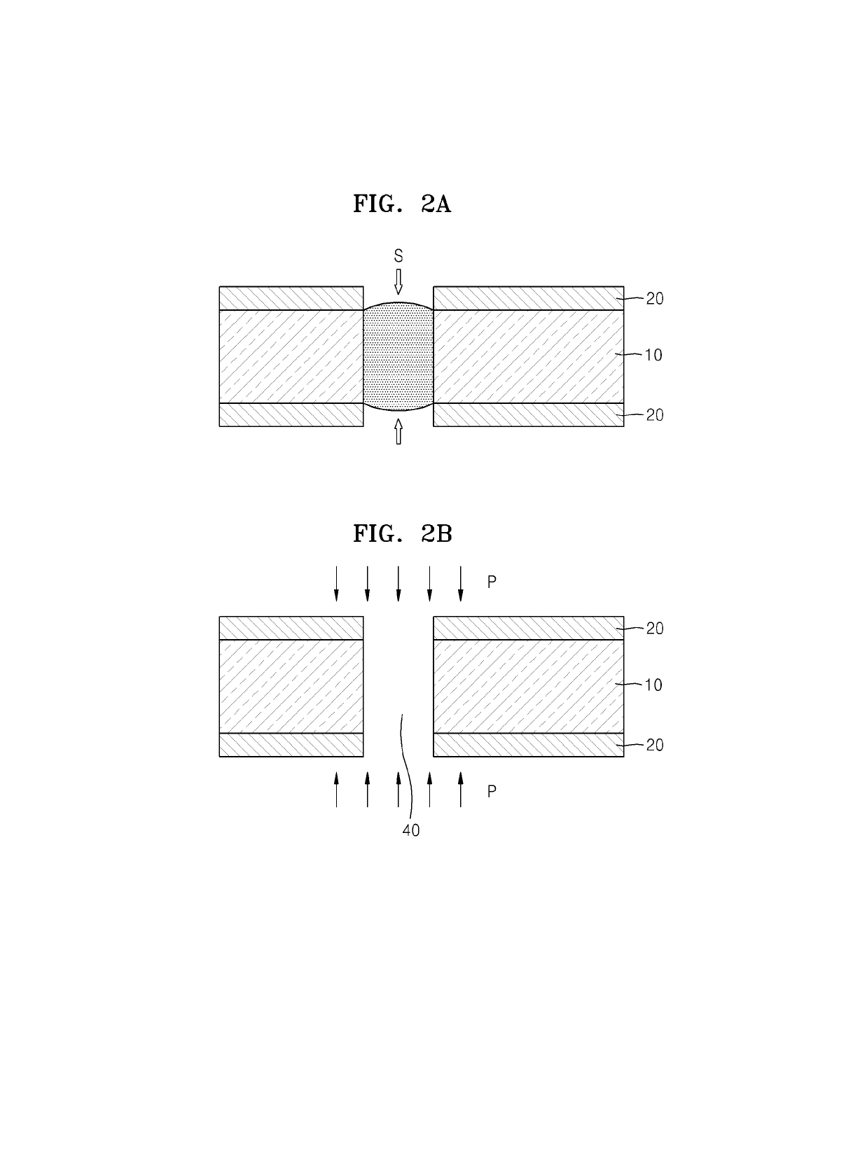

FIGS. 2A and 2B illustrate an operation of forming a via hole 40 by removing the insulating layer 10 exposed by performing the window forming operation, according to an exemplary embodiment. The operation of forming the via hole 40 includes first, a pre-treatment operation of chemically swelling an exposed insulating layer 10 (FIG. 2A) and next, an operation of physically removing the swelled insulating layer 10 (FIG. 2B). When the insulating layer 10 includes a glass structure material such as a glass cloth, a glass fiber, and glass filler (not shown) in a resin matrix, the operation of forming the via hole 40 may further include an operation of etching the insulating layer 10 by using an acid solution, such as hydrofluoric acid (HF), or a well-known glass etchant, in order to remove the glass cloth.

In the present exemplary embodiment, the operation of forming the via hole 40 is performed by sequentially performing two particular treatment operations described above, so that high speed of forming the via hole 40 and good quality of forming the via hole 40 may be simultaneously obtained. That is, each of the two operations may be performed to form a plurality of via holes simultaneously so that the speed of forming the via holes may be increased. In addition, when the via hole 40 is formed only by dissolving the insulating layer 10, inner sidewalls of the via hole 40 may be dissolved. Thus, an inner area of the insulating layer 10 disposed under the metal layers 20 may be dissolved so that the quality of forming the via hole 40 may be greatly lowered. Contrary to this, when the exposed insulating layer 10 is removed by using only a physical method without performing the pre-treatment operation of swelling the insulating layer 10, the circuit board 100 or the inner sidewalls of the via hole 40 may be damaged due to a load that is applied to the circuit board 100. Thus, according to the exemplary embodiment, the via hole 40 may be mechanically and cleanly formed by using a physical external force applied not to damage the circuit board 100 in a state where intermolecular forces of the insulating layer 10 exposed by chemical pre-treatment are reduced within a predetermined range. The physical force may be applied by using an ultrasonic wave or a high pressure water jet. As a result, the high quality of forming the via hole 40 may be simultaneously maintained with the increase of the speed of forming the via hole 40.

The operation of chemically swelling the exposed insulating layer 10 is performed to easily separate an intermolecular combination of a polymer base material used in forming the insulating layer 10 due to an external shock by reacting the insulating layer 10 with a predetermined chemical solvent S having affinity with the insulating layer 10. The swelling operation may be performed by immersing the circuit board 100 into the chemical solvent S or by spraying the chemical solvent S onto the circuit board 100.

The type of the chemical solvent S used in the chemical swelling operation is not particularly limited thereto and may be properly selected in consideration of a material used in forming the insulating layer 10, affinity with the insulating layer 10, etc. For example, the chemical solvent S may be one solvent selected from the group consisting of an alkaline solution, such as sodium permanganate or sodium hydroxide, an organic solvent, such as acetone, and other acid solutions. When a base material of the insulating layer 10 is an epoxy-based material, the chemical solvent S may be one solvent selected from the group consisting of well-known acid solutions in which epoxy swelling may occur, for example, alkaline or neutral etchants.

A temperature or time duration of the swelling operation is properly controlled to not apply an excessive load to the circuit board 100 or not to fully dissolve the insulating layer 10 due to the excessively-swollen insulating layer 10. The temperature may be controlled between a room temperature and about 90° C., and the time duration may be limited to about 10 minutes.

The operation of physically removing the swollen insulating layer 10 may use a physical external force P transferred by a high-output ultrasonic wave or high pressure water jet. The direction of the external force P may be perpendicular to the circuit board 100. The intensity of the external force P may be selected to not damage the circuit board 100. For example, an ultrasonic wave may be controlled to be in the range of about 28 to 40 kHz, and the pressure of the water jet may be controlled to be in the range of about 5 kg/cm². As described above, when the insulating layer 10 includes a glass cloth in a resin matrix, the glass etching operation using HF may be repeatedly performed several times, if necessary, before or after the ultrasonic wave or water pressure treatment has been performed, in order to remove the glass cloth that may remain due to physical removal of the insulating layer 10.

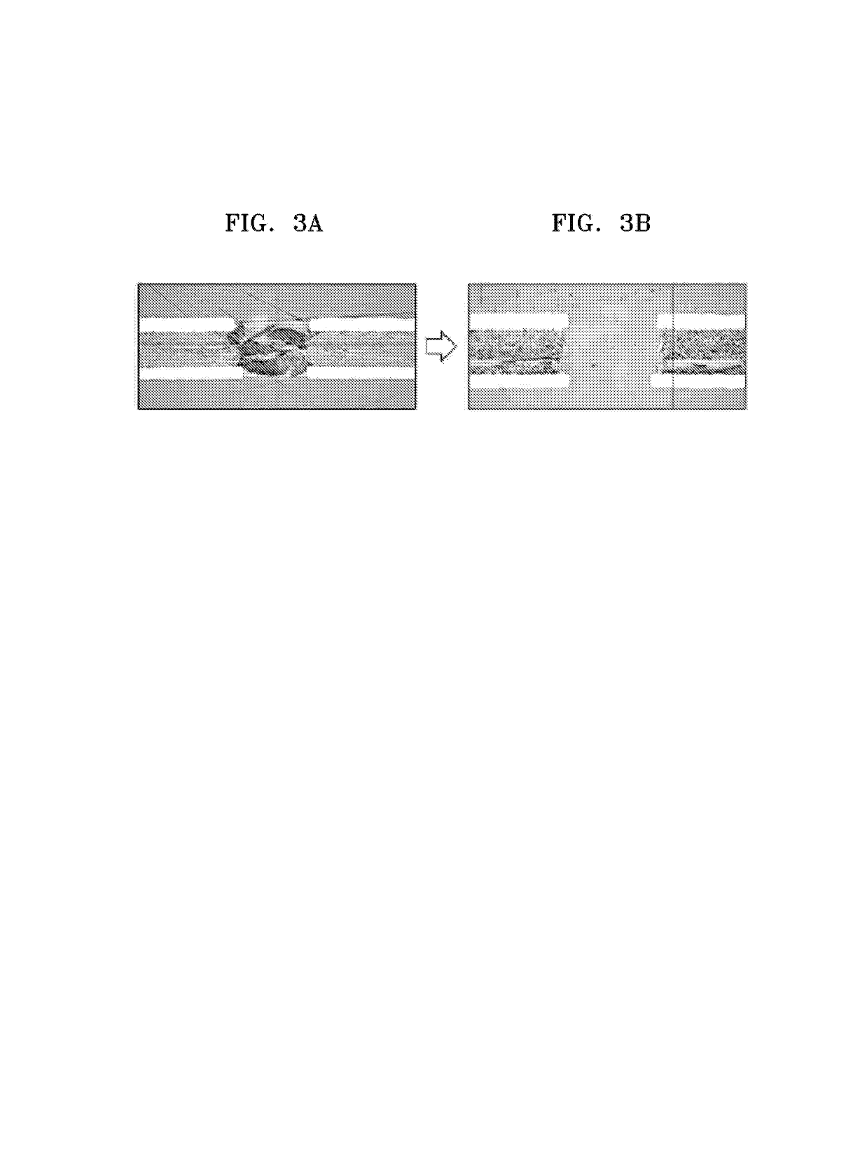

FIGS. 3A and 3B are photos showing a cross-section of the circuit board 100 in which the via hole 40 is formed to have good quality. FIG. 3A shows a state where the insulating layer 10 is chemically swollen. The swollen insulating layer 10 is swollen in a vertical direction of a window (a region from which the metal layers 20 are removed). FIG. 3B shows a state where resin and a glass cloth are removed from the insulating layer 10 by a high-output ultrasonic wave or a high pressure water jet and inner sidewalls of the via hole 40 are cleanly formed.

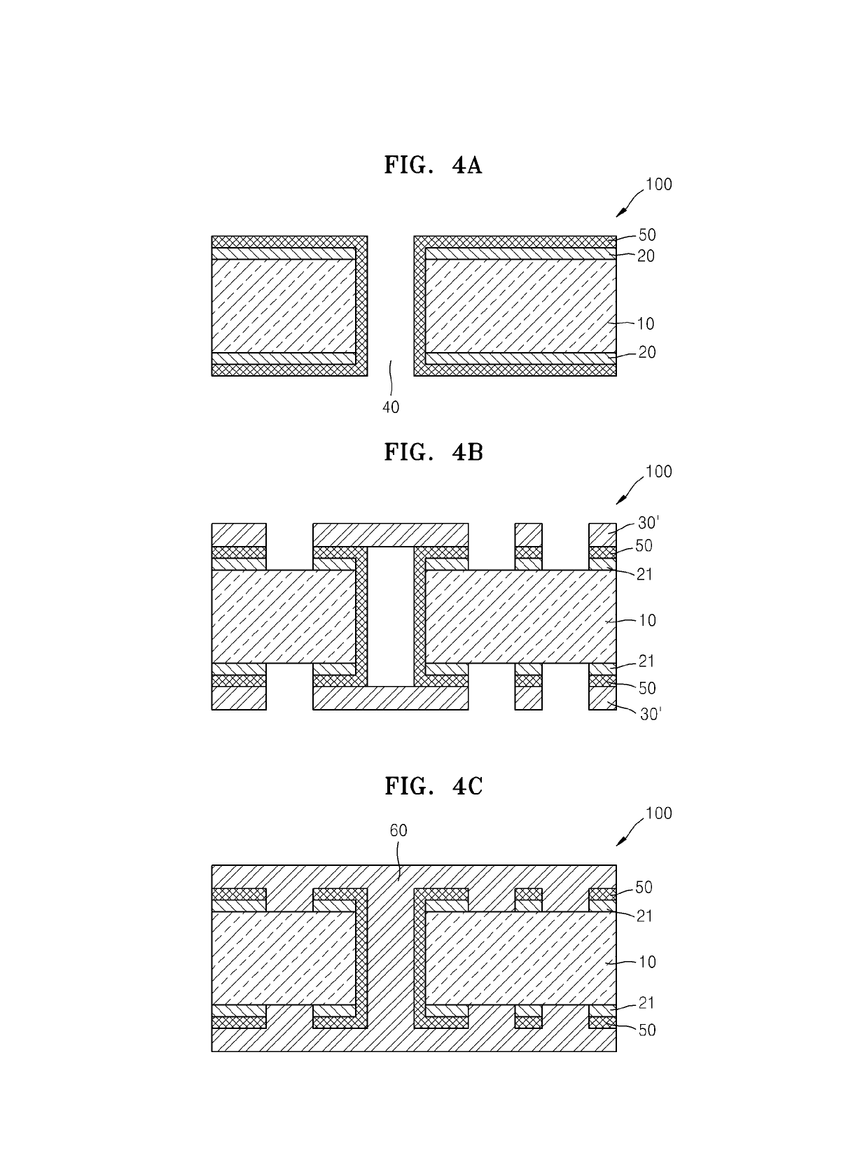

FIGS. 4A through 4C are schematic cross-sectional views of the circuit board 100 for illustrating an operation of manufacturing the circuit board after the via hole 40 has been formed, as illustrated in FIGS. 2A and 2B. Inner sidewalls of the via hole 40 are treated by performing a desmear process of removing epoxy smear attached to walls of the via hole 40 while the via hole 40 is formed in the circuit board 100 by using a solvent, such as sulfuric acid, chromic acid, or permanganate, and a plating layer 50 is formed by performing electro/electroless plating in order to conduct electricity in the metal layers 20 (see FIG. 4A). Next, a photosensitive resist 30′ is coated on the metal layers 20 by using a lithography process, and the photosensitive resist 30′ is exposed and developed. Next, preparatory patterns of the photosensitive resist 30′ corresponding to circuit patterns are formed, and then the metal layers 20 are etched to form a metal circuit layer 21 (see FIG. 4B). Subsequently, after the preparatory patterns of the photosensitive resist 30′ are removed, a photo solder resist (PSR) 60 is coated on the metal circuit layer 21, thereby completing manufacturing of the circuit board 100 (see FIG. 4C)

As described above, in a method of forming a via hole 40 in a circuit board according to an exemplary embodiment, a plurality of via holes are simultaneously formed so that costs can be reduced and the speed of forming the via hole 40 can be increased. In addition, high treatment precision can be obtained by performing two operations, a chemical swelling operation and a physical removing operation on an insulating layer 10.

While exemplary embodiments have been particularly shown and described above, those of ordinary skill in the art will appreciate that various changes may be made therein without departing from the spirit and principles of the inventive concept as defined by the following claims.

What is claimed is:

1. A method of forming a via hole in a circuit board comprising an insulating layer, and a metal layer disposed on each of top and bottom surfaces of the insulating layer, the method comprising:
selectively removing a portion of each of the metal layers where the via hole is to be formed thereby exposing the insulating layer; and
removing the exposed insulating layer,
wherein the removing of the exposed insulating layer comprises chemically swelling the exposed insulating layer and removing the swollen insulating layer.

2. The method of claim 1, wherein the insulating layer comprises a glass structure material, and the removing of the exposed insulating layer further comprises etching the glass structure material.

3. The method of claim 2, wherein the etching of the glass structure material is performed before or after the removing of the swollen insulating layer.

4. The method of claim 1, wherein the selectively removing of the portion of each of the metal layers comprises:
coating a photosensitive resist on a surface of the each of the metal layers;
exposing and developing the photosensitive resist to expose the each of the metal layers based on patterns of the via hole; and
etching the each of the exposed metal layers to remove the portion of the each of the metal layers.

5. The method of claim 4, wherein the selectively removing of the portion of each of the metal layers further comprises removing the photosensitive resist that remains after the etching of the each of the exposed metal layers.

6. The method of claim 1, wherein a solvent selected from the group consisting of acid, alkaline, and neutral etchants is used in the chemically swelling of the exposed insulating layer.

7. The method of claim 1, wherein an ultrasonic wave is used in the removing of the swollen insulating layer.

8. The method of claim 7, wherein a range between 28 and 40 kHz of the ultrasonic wave is used in the removing of the swollen insulating layer.

9. The method of claim 1, wherein a high pressure water jet is used in the removing of the swollen insulating layer.

10. The method of claim 9, wherein a pressure of 5 kg/cm² of the high pressure water jet is used in the removing of the swollen insulating layer.

11. The method of claim 1, wherein the chemically swelling of the exposed insulating layer reduces intermolecular forces of the insulating layer within a predetermined range.

12. A method of forming a via hole in a circuit board comprising, the method comprising:
providing an insulating layer with a first metal layer disposed on a first surface of the insulating layer and a second metal layer disposed on a second surface opposite of the first surface of the insulating layer;
exposing a portion of each of the first and second surfaces of the insulating layer by removing portions of each of the first and second metal layers;
reducing intermolecular forces of the insulating layer by applying a chemical solvent to the exposed portion of the insulating layer;
applying a physical external force to remove the exposed portion of the insulating layer thereby forming the via hole; and
performing a desmear process on inner sidewalls of the via hole.

13. The method of claim 12, wherein the insulating layer comprises a glass structure material, and the method further comprises etching the glass structure material.

14. The method of claim 12, wherein the exposing the portion of each of the first and second metal layers comprises:
coating a photosensitive resist on a surface of the each of the first and second metal layers;
exposing and developing the photosensitive resist to expose the each of the first and second metal layers based on patterns of the via hole; and
etching the each of the exposed first and second metal layers to expose the portion of the each of the first and second metal layers.
